(19) United States
(12) Patent Application Publication
(10) Pub. No.: US 2024/0105538 A1
(43) Pub. Date: Mar. 28, 2024

(54) METHOD FOR MAKING AN ELECTRONIC PACKAGE

(71) Applicant: JCET STATS ChipPAC Korea Limited, Incheon (KR)

(72) Inventors: SangHo SONG, Incheon (KR); HyunSu TAK, Incheon (KR); DongChul SHIN, Daegu Metropolitan City (KR)

(21) Appl. No.: 18/469,536

(22) Filed: Sep. 18, 2023

(30) Foreign Application Priority Data
Sep. 22, 2022 (CN) 202211159326.X

(51) Int. Cl. H01L 23/31; H01L 21/56; H01L 21/67; H01L 23/00; H01L 23/498; H01L 23/538; H01L 25/18

(52) U.S. Cl. CPC H01L 23/3128; H01L 21/561; H01L 21/565; H01L 21/67282; H01L 23/49827; H01L 23/5384; H01L 24/13; H01L 24/16; H01L 24/48; H01L 25/18; H01L 2224/13024; H01L 2224/16235; H01L 2224/48235

(57) ABSTRACT

An electronic package and a method for making an electronic package are provided. The electronic package comprises a substrate; a plurality of electronic components disposed on the substrate; and an encapsulant cap for encapsulating the substrate and the plurality of electronic components, wherein the encapsulant cap comprises a top surface having a first region and a second region; and wherein the first region has a first roughness, the second region has a second roughness greater than the first roughness.

### TECHNICAL FIELD

The present application generally relates to semiconductor technology, and more particularly, to a semiconductor package and a method for making an electronic package.

### BACKGROUND OF THE INVENTION

System-in-Package (SiP) is a functional electronic system or sub-system that includes two or more heterogeneous semiconductor dice, such as a logic chip, a memory, integrated passive devices (IPD), RF filters, sensors, heat sinks, or antennas. A molded underfill (MUF) process is used in the manufacturing of SiPs that underfill and mold semiconductor devices. However, in the conventional MUF process, when the semiconductor packages are demolded from a mold chase, cracks and breakages frequently occur to the semiconductor packages.

Therefore, a need exists for a process for making an electronic package with an improved yield.

### SUMMARY OF THE INVENTION

An objective of the present application is to provide a method for making an electronic package with an improved yield.

According to an aspect of the present application, an electronic package is provided. The electronic package comprises a substrate; a plurality of electronic components disposed on the substrate and an encapsulant cap for encapsulating the substrate and the plurality of electronic components, wherein the encapsulant cap comprises a top surface having a first region and a second region; and wherein the first region has a first roughness, the second region has a second roughness greater than the first roughness.

According to another aspect of the present application, an electronic package strip is provided. The electronic package strip includes a plurality of electronic packages. Each electronic package comprises a substrate, a plurality of electronic components disposed on the substrate, and an encapsulant cap for encapsulating the substrate and the plurality of electronic components, wherein the encapsulant cap comprises a top surface having a first region and a second region; and wherein the first region has a first roughness, the second region has a second roughness greater than the first roughness.

According to a further aspect of the present application, a method for making an electronic package is provided. The method comprises: placing a substrate strip with a plurality of electronic packages on a bottom mold chase, wherein each electronic package comprises a substrate and a plurality of electronic components disposed on the substrate; disposing a top mold chase over the electronic packages, wherein the top mold chase has a molding cavity to receive the electronic packages, and the molding cavity has a molding surface facing towards the electronic packages, and wherein the molding surface has a first molding region with a first roughness and a second molding region with a second roughness greater than the first roughness; injecting an encapsulant material into the molding cavity to form an encapsulant cap encapsulating the substrate and the plurality of electronic components of each electronic package, wherein the encapsulant cap comprises a top surface having a first region and a second region which correspond to the first molding region and the second molding region of the molding surface, respectively; detaching the electronic packages each encapsulated with an encapsulant cap from the bottom mold chase and the top mold chase; and separating the plurality of electronic packages from each other by singulation such that each electronic package is encapsulated with the encapsulant cap.

It is to be understood that both the foregoing general description and the following detailed description are exemplary and explanatory only and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of an electronic package 100 according to an embodiment of the present application.

FIG. 2 illustrates a top view of an electronic package strip having multiple electronic packages 100 shown in FIG. 1.

FIG. 3 illustrates a cross-sectional view of an electronic package 200 according to an embodiment of the present application.

FIGS. 4A to 4G are cross-sectional views illustrating various steps of a method for making an electronic package according to an embodiment of the present application.

FIG. 5 is a flowchart illustrating a method for making an electronic package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, cracks and breakages frequently occur to semiconductor packages when the semiconductor packages are demolded from a mold chase for a molding process. The inventors of the present application have found that the interface roughness between the semiconductor packages and the mold chase is low, so it may take a significant force required for separating the semiconductor packages (especially encapsulant caps of the semiconductor packages) from the mold chase, which may result in cracking and breakage issue of the semiconductor packages. In particular, when the encapsulant cap is demolded from the mold chase, two ends of the encapsulant cap can be detached from the mold chase, but the middle portion of the encapsulant cap may still tightly stick to the mold chase, thereby the electronic package may crack or break at the middle portion or close to the middle portion. However, the low-roughness encapsulant cap surfaces of semiconductor packages are generally required for laser marking because a smooth surface may improve the resolution of laser marking. Typically, a surface where laser marking is implemented requires relatively low roughness, such as less than 0.8 μm.

In order to address the above issue, the inventors of the present application conceived a new electronic package having an encapsulant cap with two types of roughness, and a method for making an electronic package, as elaborated below with more details.

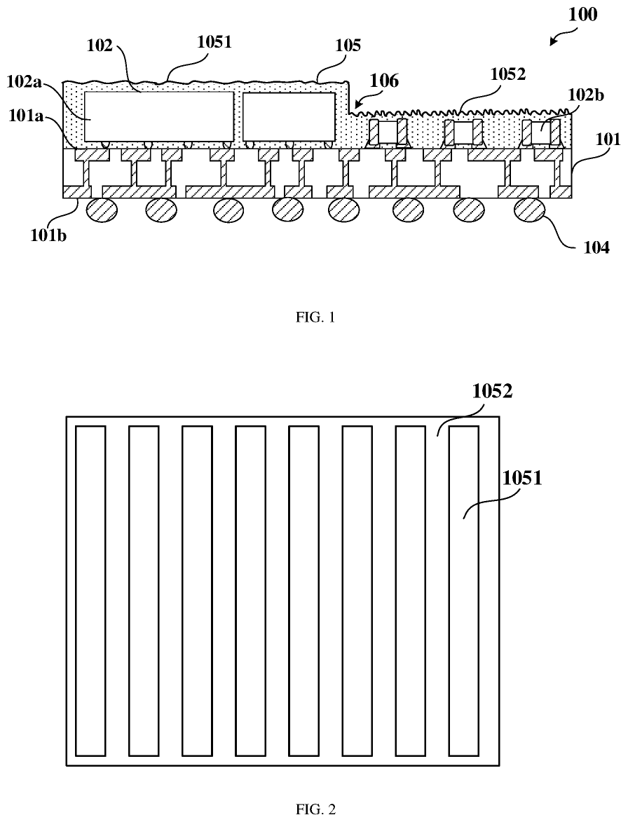

FIG. 1 illustrates a cross-sectional view of an electronic package 100 according to an embodiment of the present application.

As shown in FIG. 1, the electronic package 100 includes a substrate 101 with a top surface 101a and a bottom surface 101b. In some embodiments, the substrate 101 may be a printed circuit board (PCB) and may include a redistribution structure (RDS) having one or more dielectric layers and one or more conductive layers between and through the dielectric layers. The conductive layers may define pads, traces, and plugs through which electrical signals or voltages can be distributed horizontally and vertically across the RDS. In some embodiments, the RDS may include a plurality of conductive patterns formed on both or either of the top and bottom surfaces of the substrate 101.

A plurality of electronic components 102 can be disposed on the top surface 101a of the substrate 101, with at least a portion of them covered by an encapsulant cap 105. Furthermore, a plurality of bumps 104 can be attached to the substrate 101 to facilitate the integration of the electronic package 100 with an external electronic device or system. In particular, the plurality of electronic components 102 are mounted on the top surface 101a of the substrate 101 and are encapsulated by the encapsulant cap 105. After being encapsulated, the electronic package 100 can be laser-marked with certain information of the electronic package 100. For example, the information may can be marked on a top surface of the encapsulant cap 105 including a specification and/or manufacturing information of the electronic package 100.

In the embodiment, the top surface 101a of the encapsulant cap 105 has a first region 1051 and a second region 1052. The first region 1051 has a first roughness, and the second region 1052 has a second roughness greater than the first roughness. The encapsulant cap 105 with two different roughness can bring many benefits. For example, during the MUF process, since the first roughness is lower than the second roughness, the second region having the second roughness is less likely to adhere to the mold chase than the first region when the encapsulant cap 105 is demolded from the mold chase. As such, it is much easier to remove the encapsulant cap 105 and the electronic package 100 from the mold chase, thereby avoiding cracking of the electronic packages. It should be noted that since the two-roughness top surface of the encapsulant cap 105 is to address the cracking issue during demolding, such top surface should be formed in a single molding and demolding process, rather than formed separately in two or more molding and demolding processes.

In some embodiments, the first region 1051 is higher than the second region 1052 relative to the substrate 101 as shown in FIG. 1, and optionally the thickness of the encapsulant cap 105 in the first region 1051 which encapsulates first electronic components 102a may be greater than the thickness of the encapsulant cap 105 in the second region 1052 which encapsulates the second electronic components 102b. The electronic package with such varying-thickness encapsulant cap may further compensate for a warpage effect of the electronic package 100. In some embodiments, the top surface of the encapsulant cap 105 may include more than two regions with respective thicknesses.

In some embodiments, the first electronic components 102a and/or the second electronic components 102b may include a plurality of semiconductor dices, semiconductor devices and/or discrete devices. For example, the electronic components may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. The electronic components 102 may also be passive devices such as capacitors, inductors, or resistors. In the example shown in FIG. 1, the first electronic components 102a may include two active devices which have bigger form factors, and the second electronic components 102b may include three passive devices which have smaller form factors, but the scope of this application is not limited thereto. The first electronic components 102a and the second electronic components 102b can be mounted on the top surface 101a of the substrate 101 using any suitable surface mounting techniques.

In some embodiments, the encapsulant cap 105 is formed by an injection molding process such as the MUF process, which may reduce or prevent moisture and other contaminants from affecting the functionality and reliability of the electronic package. In some embodiments, an encapsulant material of the encapsulant cap 105 may be made of a general molding compound resin in a liquid form, for example, an epoxy-based resin, but the scope of this application is not limited thereto. In some embodiments, the encapsulant material is non-conductive material and provides structural support.

One or more laser markings can be formed in the first region 1051 of the top surface of the encapsulant cap 105, which may have the first roughness less than 0.8 μm. In some embodiments, the first roughness is in a range of 0.2 μm to 0.4 μm, in a range 0.4 μm to 0.6 μm or in a range of 0.6 μm to 0.8 μm. In some other embodiments, the first roughness is less than 0.4 μm. In some embodiments, the second roughness is greater than 1.8 μm. On the contrary, the second roughness of the second region 1052 is in a range of 1.8 μm to 3.2 μm, in a range of 3.2 μm to 6.3 μm or in a range of 6.3 μm to 12.5 μm. In some other embodiments, the second roughness is greater than 12.5 μm.

In some preferred embodiment, at a border between the first region 1051 and the second region 1051, a transition region 106 may be formed at the top surface of the encapsulant cap 105. The transition region 106 may be for example a rounded step or the like, which provides a smooth transition from the higher first region 1051 to the lower second region 1052. Such smooth transition can reduce or avoid stress concentration at the border between the first region 1051 and the second region 1051, thereby reducing the risk of cracking there.

FIG. 2 illustrates a top view of an electronic package strip having multiple electronic package 100 shown in FIG. 1.

As shown in FIG. 2, since the electronic packages are arranged in a row on the electronic package strip and connected together, the encapsulant cap 105 may include a plurality of first regions 1051 and a plurality of second regions 1052. Each of the first regions 1051 is of a rectangular shape, and each of the second regions 1052 is adjacent to a first region 1051 and surrounds the first region 1051. In some embodiments, the first regions and the second regions may be arranged in other layouts. For example, the first regions and the second regions may intersect with each other in form of an array with multiple rows and columns. It can be appreciated that the arrangement of the first and second regions can be configured by the mold chase for forming the encapsulant caps of the electronic packages. These integrated electronic packages can later be separated from each other.

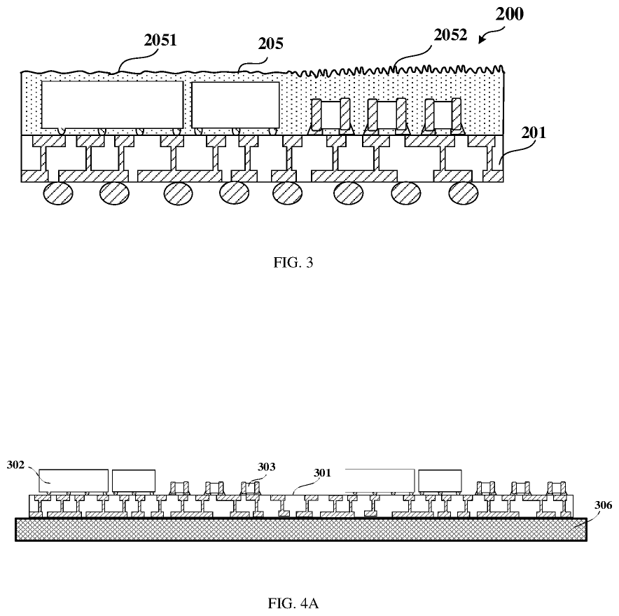

FIG. 3 illustrates a cross-sectional view of an electronic package 200 according to another embodiment of the present application.

As shown in FIG. 3, different from the electronic package 100 illustrated in FIG. 1 the electronic package 200 includes an encapsulant cap 205 with a generally flat top surface. The top surface has a first region 2051 with a first roughness and a second region 2052 with a second roughness greater than the first roughness. In the embodiment, the first region 2051 and the second region 2052 have generally the same height, that is, the encapsulant cap 205 has a uniform thickness above a substrate 201.

It should be noted that although two regions 2051 and 2052 are shown in FIG. 3, more regions with respective roughness can be formed on the top surface of the encapsulant cap 205. In addition, each of the regions may have subregions that are not adjacent to each other. For example, the second region may have a cross shape when viewed from the top of the electronic package 200, and the cross-shaped second region may separate the first region into four subregions each close to a corner of the top surface of the electronic package 200. In some other embodiments, the second region may have a grid shape, which may separate the first region into multiple blocks. It is much easier to detach from the mold chase the electronic packages with such separated or disconnected first region.

In some embodiments, the first region 2051 may occupy a smaller area of the top surface of the encapsulant cap 205 than the second region 2052, as long as the surface area required for laser marking or other similar purposes can be satisfied. For example, the first region 2051 may occupy less than 50% of the top surface of the encapsulant cap 205. In some examples, the first region 2051 may occupy less than 40%, less than 30%, less than 20% or less than 10% of the top surface of the encapsulant cap 205. In some embodiments, the first region 2051 may occupy an area of smaller than 5 cm² of the top surface of the encapsulant cap 205, or smaller than 1 cm² of the top surface of the encapsulant cap 205, or even smaller.

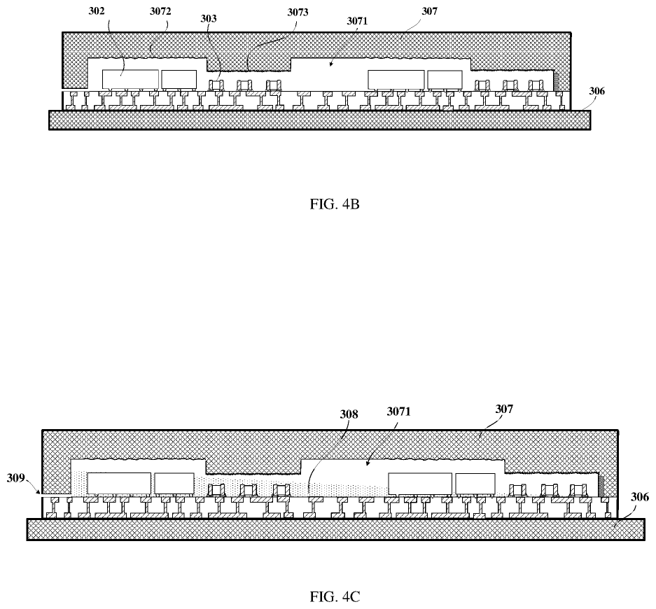

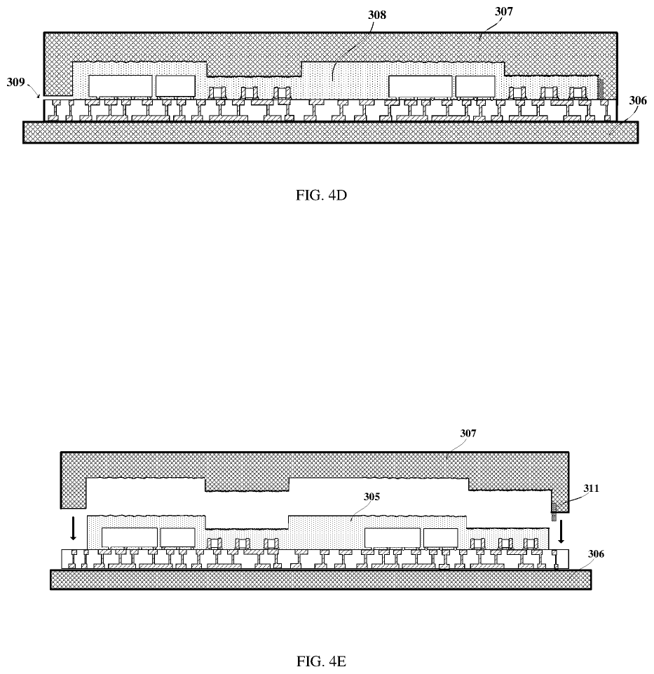

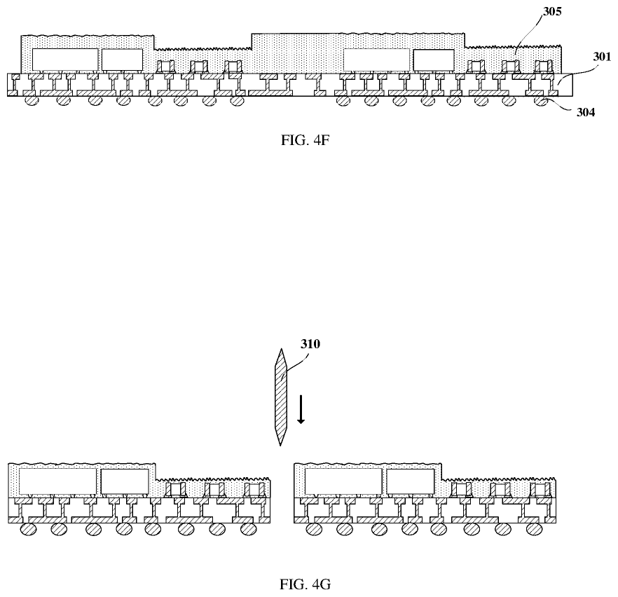

Referring to FIGS. 4A to 4G, various step of a method for making an electronic package is illustrated according to an embodiment of the present application. For example, the method may be used to make the electronic package 100 shown in FIG. 1 or the electronic package 200 shown in FIG. 3. In the following, the method will be described with reference to FIGS. 4A to 4G in more details.

As shown in FIG. 4A, a substrate strip having a plurality of electronic packages are placed on a bottom mold chase 306. Each electronic package may take up a portion of the layout of the substrate strip and may be separated from adjacent electronic packages later in a singulation process performed to the substrate strip at respective singulation channels such as saw streets. The plurality of electronic packages assembled in the strip form can be processed simultaneously to improve the productivity of the manufacturing process. Each electronic package includes a substrate 301 and a plurality of electronic components, including first electronic components 302 and second electronic components 303.

The bottom mold chase 306 may be a part of a mold chase for molding, and mate with a top mold chase 307 which is the other part of the mold chase. In the embodiment, the bottom mold chase 306 is generally flat to support the substrate strip which is flat as well. In some other embodiments, the bottom mold chase may be a carrier with another shape that may fit for supporting and placing the substrate strip.

Afterwards, as shown in FIG. 4B, the top mold chase 307 is disposed over the bottom mold chase 306 and covers the electronic packages. The top mold chase 307 and the substrate strip forms a generally sealed chamber where the molding process is performed. In particular, the top mold case 307 may be pressed against the bottom mold chase 306, for example, through clamping to avoid relative movement of the substrate strip between the top mold chase 307 and the bottom mold chase 306. In the embodiment, the top mold chase 307 includes a molding cavity 3071 to receive the electronic packages, and the depth of the molding cavity 3071 should be greater than the heights of the electronic packages to ensure fluid communication within the entire molding cavity 3071. In particular, the molding cavity 3071 has a molding surface facing toward the electronic packages. The molding surface has a first molding region 3072 of a first roughness and a second molding region 3073 of a second roughness, and the second roughness is greater than the first roughness. As for each electronic package, the first molding region 3072 is aligned with the first electronic components 302 and the second molding region 3073 is aligned with the second electronic components 303. Furthermore, the top mold chase 307 has a first depth in the first molding region 3072, which is greater than a second depth in the second molding region 3073. In some embodiments, the top mold chase 307 may be of an integral structure specifically used for certain electronic packages. In some other embodiments, the top mold chase 307 may be of an assembled structure which allows for change of the molding regions 3072 and 3073. In this way, the roughness/depth of the first molding regions 3072 and the roughness/depth of the second molding regions 3073 can be changed by changing the molding surfaces assembled within the mold cavity 3071, such that various types of electronic packages in compliance with different form factor standards or requirements can be encapsulated by the top mold chase 307 without significant change to the entire top mold chase 307.

In some embodiments, the mold chase including the top mold chase 307 and the bottom mold chase 306 may be formed of stainless steel, ceramics, copper, aluminum, or other types of materials. In some embodiments, the design of the mold chase including its configuration and layout can be modified according to the size and number of electronic packages to be disposed within the mold chase.

Afterwards, as shown in FIG. 4C, there is an inlet port 309 at a sidewall of the top mold chase 307, through which an encapsulant material 308 can be injected into the molding cavity 3071. Furthermore, there is an air vent on the top mold chase 307 to release air during the injection of the encapsulant material 308. It can be appreciated that the configuration of the inlet port and/or air vent of the top mold chase 307 can be modified as desired in some embodiments. Specifically, the encapsulant material 308 is injected through the inlet port 309 from a dispenser into the molding cavity 3071 to encapsulate the substrate 301 and the plurality of electronic components thereon under proper temperature and pressure. Since all the electronic packages may be encapsulated in a single molding process simultaneously, the encapsulant material 308 injected into the molding cavity 3071 through the inlet port 309 can flow and fully fill in the molding cavity 3071, as illustrated in FIG. 4D. The encapsulant material 308 is then cured and solidified to form an encapsulant cap 305 for each electronic package, for example, in a thermal curing process. As such, the roughness of the top surface of each encapsulant cap 305 is substantially equal to the roughness of the corresponding molding surface of the molding cavity 3071, because they tightly adhere to each other during the injection molding process.

As shown in FIG. 4E, the substrate strip with electronic packages each covered by an encapsulant cap 305 can be detached from the mold chase. In particular, the top mold chase 307 further includes an eject pin 311 that is inserted at one side of the top mold chase 307. When the encapsulant caps 305 are detached from the top mold chase 307, the eject pin 311 can protrude from the top mold chase 307 and be pressed against a peripheral portion of the substrate strip. In this way, the electronic packages can be pushed away from the top mold chase 307, together with the respective encapsulant caps 305 formed thereon, thereby being demolded from the top mold chase 307. In some embodiments, the top mold chase 307 may include two or more eject pins that are inserted at both sides of the top mold chase 307 or more locations of the top mold chase 307, for simultaneously detaching the encapsulant caps 305 from the top mold chase 307. For example, the eject pins 311 may be pressed against the encapsulant material formed over the substrate strip instead of the substrate strip itself.

Then, as shown in FIG. 4F, a plurality of bumps 304 is formed under each substrate 301 after detaching the substrate 301 from the top mold chase 307 and the bottom mold chase 306 for subsequent semiconductor packaging. In some embodiments, the plurality of bumps 304 can be formed using one of or any combination of the following process: evaporation, electrolytic plating, electroless plating, ball drop, or screen-printing process.

Afterwards, the substrate strip with the electronic packages can be singulated into individual electronic packages as shown in FIG. 4G. Specifically, the electronic packages can be singulated at singulation channels using a saw blade or a laser cutting tool 310, for example. Furthermore, laser marking can be added onto the electronic packages at their respective surfaces with a lower roughness, as desired in certain applications.

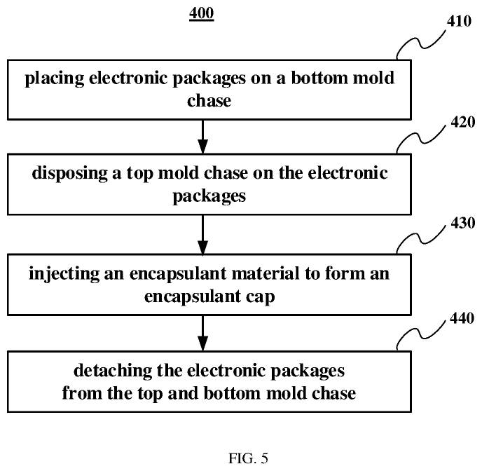

Referring to FIG. 5, a flowchart illustrating a method 400 for making an electronic package is illustrated according to an embodiment of the present application. As illustrated in FIG. 5, the method 400 may begin with block 410, a plurality of electronic packages is placed on a bottom mold chase. Then, at block 420, a top mold chase is disposed over the electronic packages to form a molding cavity. The molding cavity has a molding surface facing towards the electronic packages, and the molding surface has a first molding region with a first roughness and a second molding region with a second roughness greater than the first roughness. At block 430, an encapsulant material is injected into the molding cavity of the mold chase to form an encapsulant cap over each electronic package. The encapsulant cap includes a top surface having a first region and a second region which correspond to the first molding region and the second molding region of the molding surface, respectively. At block 440, the electronic packages with respective encapsulant caps are detached from the top mold chase and the bottom mold chase. Optionally, the electronic packages can be separated from each other by singulation such that each electronic package is encapsulated with an encapsulant cap. Alternatively, an electromagnetic interference (EMI) shielding layer may also be formed after forming the encapsulant cap.

The discussion herein included numerous illustrative figures that showed various portions of an electronic package and a method for making the same. For illustrative clarity, such figures did not show all aspects of each example assembly. Any of the example devices and/or methods provided herein may share any or all characteristics with any or all other devices and/or methods provided herein. It could be understood that embodiments described in the context of one of the devices or methods are analogously valid for the other devices or methods. Similarly, embodiments described in the context of a device are analogously valid for a method, and vice versa. Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic package, comprising:
a substrate;
a plurality of electronic components disposed on the substrate; and
an encapsulant cap for encapsulating the substrate and the plurality of electronic components, wherein the encapsulant cap comprises a top surface having a first region and a second region; and wherein the first region has a first roughness, the second region has a second roughness greater than the first roughness.

2. The electronic package of claim 1, wherein the top surface of the encapsulant cap has a laser marking in the first region.

3. The electronic package of claim 1, wherein the encapsulant cap is formed by injection molding.

4. The electronic package of claim 1, wherein the first region is higher than the second region relative to the substrate.

5. The electronic package of claim 1, wherein the first roughness is less than 0.8 μm, and the second roughness is greater than 1.8 μm.

6. An electronic package strip comprising a plurality of electronic packages, each of the electronic package comprising:
a substrate;
a plurality of electronic components disposed on the substrate; and
an encapsulant cap for encapsulating the substrate and the plurality of electronic components, wherein the encapsulant cap comprises a top surface having a first region and a second region; and wherein the first region has a first roughness, the second region has a second roughness greater than the first roughness.

7. The electronic package strip of claim 6, wherein the top surface of the encapsulant cap has a laser marking in the first region, and the encapsulant cap is formed by injection molding.

8. A method for making an electronic package, the method comprising:
placing a substrate strip with a plurality of electronic packages on a bottom mold chase, wherein each electronic package comprises a substrate and a plurality of electronic components disposed on the substrate;
disposing a top mold chase over the electronic packages, wherein the top mold chase has a molding cavity to receive the electronic packages, and the molding cavity has a molding surface facing towards the electronic packages, and wherein the molding surface has a first molding region with a first roughness and a second molding region with a second roughness greater than the first roughness;
injecting an encapsulant material into the molding cavity to form an encapsulant cap encapsulating the substrate and the plurality of electronic components of each electronic package, wherein the encapsulant cap comprises a top surface having a first region and a second region which correspond to the first molding region and the second molding region of the molding surface, respectively;
detaching the electronic packages each encapsulated with an encapsulant cap from the bottom mold chase and the top mold chase; and
separating the plurality of electronic packages from each other by singulation such that each electronic package is encapsulated with the encapsulant cap.

9. The method of claim 8, wherein the top mold chase has a first depth in the first molding region greater than a second depth in the second molding region.

10. The method of claim 8, wherein the first roughness is less than 0.8 μm, and the second roughness is greater than 1.8 μm.

11. The method of claim 8, further comprising:
forming a laser marking in the first region of the top surface of the encapsulant cap.
